(19) United States
(12) Patent Application Publication
(10) Pub. No.: US 2013/0292655 A1
(43) Pub. Date: Nov. 7, 2013

(54) Method for producing an electronic component and electronic component

(71) Applicants: Dirk Becker, Langquaid (DE); Erwin Lang, Regensburg (DE); Thilo Reusch, Regensburg (DE)

(72) Inventors: Dirk Becker, Langquaid (DE); Erwin Lang, Regensburg (DE); Thilo Reusch, Regensburg (DE)

(73) Assignee: OSRAM OPTO SEMICONDUCTORS GMBH, Regensburg (DE)

(21) Appl. No.: 13/823,921

(22) PCT Filed: Jul. 28, 2011
(86) PCT No.: PCT/EP11/62969

§ 371 Date: Jul. 22, 2013

(30) Foreign Application Priority Data
Sep. 15, 2010 (DE) 10 2010 040 839.5

(51) Int. Cl. H01L 51/56; H01L 51/52

(52) U.S. Cl. CPC H01L 51/56; H01L 51/5203
USPC 257/40; 438/98

(57) ABSTRACT

A method for producing an electronic component may include: applying an electrode growth layer on or above a layer structure by means of an atomic layer deposition method; and applying an electrode on the electrode growth layer, wherein the electrode growth layer is applied with a layer thickness in a range of approximately 1.5 nm to approximately 28 nm.

### RELATED APPLICATIONS

The present application is a national stage entry according to 35 U.S.C. §371 of PCT application No.: PCT/EP2011/062969 filed on Jul. 28, 2011, which claims priority from German application No.: 10 2010 040 839.5 filed on Sep. 15, 2010.

### TECHNICAL FIELD

Various embodiments relate to a method for producing an electronic component, and to an electronic component.

### BACKGROUND

In large-area applications, thin electrical contacts of electronic components, such as optoelectronic components, for example, in particular as top contacts, presuppose a good energization or conductivity and, if appropriate, sufficient transparency.

### SUMMARY

In various embodiments, an electronic component including an electrode having, by comparison with the prior art, a reduced thickness and, if appropriate, improved transparency and conductivity is provided.

In various embodiments a method for producing an electronic component includes: applying an electrode growth layer on or above a layer structure by means of an atomic layer deposition method, and applying an electrode on the electrode growth layer.

In various embodiments, an electronic component includes a substrate, an electrode growth layer on the substrate, and an electrode on the electrode growth layer. The electrode growth layer is embodied as an atomic layer deposition layer.

An atomic layer deposition method should be understood to mean, for example, any method in which monolayers of atoms can be applied individually. In various embodiments, an atomic layer deposition method should be understood to mean a vapor deposition method in which, by way of example, the starting substances are admitted into a reaction chamber cyclically one after another. In various embodiments, the partial reactions of the atomic layer deposition method are self-limiting, that is to say that the starting substance of a partial reaction does not react with itself or ligands of itself, which limits the layer growth of a partial reaction to a maximum of one monolayer of atoms with an arbitrary length of time and quantity of gas.

The various configurations of these embodiments are applicable in the same way, in so far as is expedient, to the method for producing an electronic component and also to the electronic component.

By virtue of the use of an atomic layer deposition method for applying the growth layer, what can be achieved in various embodiments is that the growth layer can be deposited particularly thinly and with high layer thickness reproducibility. A further advantage of the use of the atomic layer deposition method can be seen in the fact that the intermediate layer can also be formed from a plurality of very thin plies deposited directly one on top of another (then also designated as “nanolaminate”, NL). A targeted adaptation of the composition and morphology of the growth layer (intermediate layer) to the transparent metallic top electrode is possible as a result. Furthermore, damaging influences on the organic system such as can occur during sputtering deposition (plasma, radiation, fast ions) are generally avoided in atomic layer deposition. This can be advantageous in particular in the case of an organic photovoltaic component, for example an organic photovoltaic cell, or an organic optoelectronic component such as, for example, an organic light emitting diode (OLED). Atomic layer deposition is additionally distinguished by a particularly uniform and conformal coating of surfaces. As a result, the intermediate layer, or to put it another way the electrode growth layer, can be embodied, in particular, such that a material exchange between metallic top electrode and organic layers underneath is suppressed. Such a diffusion barrier prevents the degradation of the organic component on account of diffusion at the interface between top electrode—organic system. Moreover, a further advantage in the use of an atomic layer deposition method can be seen in the relatively low process temperatures, which protects the processed layers with regard to their thermal loading.

The electrode may be an anode or a cathode. The electrode may have hole-injecting or electron-injecting functions.

In one configuration of the method, the electrode growth layer may be applied with a layer thickness in a range of 0.1 nm to 200 nm, for example with a layer thickness in a range of 0.1 nm to 10 nm, for example with a layer thickness in a range of 1 nm to 8 nm, for example with a layer thickness in a range of 3 nm to 3.5 nm, for example with a layer thickness of greater than or equal to 1.5 nm. In various configurations, the layer thickness of the electrode growth layer may be, for example, less than or equal to 7 nm.

Furthermore, a plurality of partial layers which form the electrode growth layer may be applied one on top of another by means of an atomic layer deposition method. The partial layers together clearly form a nanolaminate.

The electrode growth layer may be formed or include: one or a plurality of fundamentally arbitrary materials which may be deposited by means of an atomic layer deposition method. The material or materials may include one dielectric or a plurality of dielectrics and/or one electrically conductive material or a plurality of electrically conductive materials (for example metal(s)). Thus, the electrode growth layer may include, for example: one oxide or a plurality of oxides, one nitride or a plurality of nitrides, and/or one carbide or a plurality of carbides. By way of example, the electrode growth layer includes at least one layer composed of indium-doped tin oxide and a layer composed of aluminum-doped zinc oxide. The electrode growth layer may be formed from a material or include a material which is selected from transparent conductive or transparent nonconductive oxides such as, for example, metal oxides, such as zinc oxide, tin oxide, cadmium oxide, titanium oxide, indium oxide or indium-doped tin oxide (ITO), aluminum-doped zinc oxide (AZO), dizinc tin tetraoxide (e.g. Zn₂SnO₄), cadmium tin oxide (e.g. CdSnO₃), zinc tin trioxide (e.g. ZnSnO₃), manganese indium oxide (e.g. MgIn₂O₄), gallium indium oxide (e.g. GalnO₃), zinc indium oxide (e.g. Zn₂In₂O₅) or indium tin oxide (e.g. In₄Sn₃O₁₂) or mixtures and alloys of different transparent conductive oxides or transparent nonconductive oxides. Since the electrode growth layer is a very thin layer, it need not necessarily be conductive. The electrode growth layer may therefore include dielectric oxides such as aluminum oxide (e.g. Al₂O₃), tungsten oxide (e.g. WO₃), hafnium oxide (e.g. HfO₂), titanium oxide (e.g. TiO₂), lanthanum oxide (e.g. LaO₂), silicon oxide (e.g. SiO₂), rhenium oxide (e.g. Re₂O₇), molybdenum oxide (e.g. MoO₃), vanadium oxide (e.g. V₂O₅) and the like or can be formed from such and from mixtures and alloys thereof. Furthermore, the growth layer can also be embodied or have been embodied as dielectric nitrides such as, for example, boron nitride, titanium nitride, tungsten nitride, silicon nitride, tantalum nitride, chromium nitride, hafnium nitride, lanthanum nitride, zirconium nitride, or mixtures thereof. Furthermore, in various embodiments, the growth layer can also be embodied or have been embodied as dielectric carbides such as, for example, boron carbide, titanium carbide, tungsten carbide, silicon carbide, tantalum carbide, chromium carbide, hafnium carbide, lanthanum carbide, zirconium carbide, or mixtures thereof.

In various embodiments, any (electrical conductive or dielectric) material which may be deposited by means of an atomic layer deposition method can be provided for the intermediate layer or the partial intermediate layers.

In one configuration, the contribution of the electrode growth layer to the lateral current conduction is usually negligible.

The surface of the electrode growth layer may be prepared or designed in a suitable manner, for example, in order to make possible a uniform or homogeneous deposition of a metal layer to be deposited thereon. In one embodiment, the surface of the electrode growth layer can have an amorphous or substantially amorphous structure or an amorphous or substantially amorphous surface. A fully amorphous structure can be confirmed for example by means of X-ray diffraction (XRD diffractograms) (no discrete Bragg reflections are obtained).

In accordance with another development, the electrode can be formed by applying a metal layer having a layer thickness of less than or equal to 30 nm.

The metal layer can have a thickness of less than or equal to 15 nm, for example of less than or equal to 12 nm.

In embodiments in which, in particular, the transparency of the metal layer is of importance, the thickness of the metal layer can be for example less than or equal to 14 nm, for example less than or equal to 11 nm. For example, the thickness of a metal layer including an Ag layer or a layer composed of an Ag alloy (e.g. a layer composed of an Ag—Sm alloy or composed of an Ag—Mg or Ag—Ca or AgPdCu alloy) can be less than or equal to 14 nm, in particular less than or equal to 11 nm, for example between approximately 9 nm and approximately 10 nm.

The electrode applied, for example grown, on the electrode growth layer may consist of the metal layer or include one or further layers or functional layers.

In accordance with yet another development, the metal layer can be formed with a layer thickness homogeneity of ±10%, for example with a layer thickness homogeneity of ±5%.

The term “thickness homogeneity” as used herein means that the metal layer can have a layer thickness that is virtually constant over its substantial or complete length, i.e. a layer thickness having a maximum deviation of e.g. ±10%. This can be achieved, for example, in particular by means of the (thin) electrode growth layer arranged below the metal layer. The maximum layer thickness of a “30 nm thick” metal layer can therefore be, for example, a maximum of 33 nm, and the maximum layer thickness of a “12 nm thick” metal layer may be, for example, a maximum of 13.2 nm.

In a further embodiment, the sheet resistance of the electrode on the electrode growth layer is less than or equal to 6Ω/□. The sheet resistance can be, in particular, less than or equal to 5Ω/□. By way of example, the sheet resistance can be in a range of 4Ω/□ and 5Ω/□.

The term “sheet resistance” as used herein denotes the isotropic resistivity of a layer relative to the thickness thereof. The sheet resistance can be measured, for example, with the aid of the four-point method. Alternatively, a sheet resistance can also be measured by the special Van-Der-Pauw method.

Therefore, in various embodiments, the sheet resistance can be lower than has been customary hitherto in the prior art with comparable electrode layers deposited on a different substrate than the electrode growth layer in accordance with various embodiments. The arrangement in accordance with various embodiments can make it possible to achieve a uniform energization of the thin (growth) electrode—for example in optoelectronic components with sufficient transparency.

The metal layer of the electrode includes, for example, at least one of the following metals: aluminum, barium, indium, silver, copper, gold, samarium, magnesium, calcium and lithium and combinations thereof. The metal layer can alternatively consist of one of the abovementioned metals or a compound including one of said metals or composed of a plurality of said metals, for example an alloy.

The electrode can be used in transparent and nontransparent electronic, optical or electro-optical components. The electrode arranged on the electrode growth layer may be used as a top contact, substrate contact and/or intermediate contact.

In various configurations, the sheet resistance of the electronic component can be less than or equal to 8Ω/□, for example less than or equal to 5Ω/□.

The electronic component can be formed or have been formed as an organic electronic component. In this configuration, furthermore an additional electrode and at least one organic functional layer arranged between the electrode and the additional electrode can be formed or have been formed in the electronic component.

The additional electrode may be a cathode. The electrode and the additional electrode are electrically contact-connected in a suitable manner.

The electrode and/or the additional electrode arranged on the growth layer are/is—as indicated above—also designated as growth electrode. The growth electrode may be provided as an anode or cathode or form part thereof.

The electrode which is not arranged on an electrode growth layer may be formed from a material or include a material selected from metals such as aluminum, barium, indium, silver, gold, magnesium, chromium, nickel, vanadium, calcium and lithium and combinations thereof or a compound thereof, in particular an alloy, and transparent conductive oxides such as, for example, metal oxides, such as zinc oxide, tin oxide, cadmium oxide, titanium oxide, indium oxide or indium-doped tin oxide (ITO), aluminum-doped zinc oxide (AZO), dizinc tin tetraoxide (e.g. Zn₂SnO₄), cadmium tin oxide (e.g. CdSnO₃), zinc tin trioxide (e.g. ZnSnO₃), manganese indium oxide (e.g. MgIn₂O₄), gallium indium oxide (e.g. GalnO₃), zinc indium oxide (e.g. Zn₂In₂O₅) or indium tin oxide (e.g. In₄Sn₃O₁₂) or mixtures of different transparent conductive oxides.

Consequently, the component, without being restricted thereto, can be embodied for example as an optoelectronic component, for example as an organic electronic component, such as, for example, as a solar cell, as a phototransistor, light emitting diode and the like, for example as an organic light emitting diode (OLED).

The organic electronic component is e.g. an optoelectronic component or a radiation emitting device.

The layer structure may have a substrate.

A “substrate” as used herein may include, for example, a substrate usually used for an electronic component. The substrate can be a transparent substrate. However, the substrate can also be a nontransparent substrate. By way of example, the substrate may include glass, quartz, sapphire, plastic film(s), metal, metal film(s), silicon wafers or some other suitable substrate material. A metal substrate is used, for example, if the electrode growth layer is not arranged directly thereon. In various configurations, substrate is understood to mean the layer on which all other layers are subsequently applied during the production of the electronic component. Such subsequent layers can be layers required for radiation emission e.g. in an optical electronic component or a radiation emitting device.

The term “layer” or “layer structure” as used herein may denote an individual layer or a layer sequence composed of a plurality of thin layers. In particular, the functional layers, for example organic functional layers, may be formed from a plurality of layers. The metal layer and the electrode growth layer are single-layered or multilayered.

The term “arranged one on top of another” as used herein means, for example, that one layer is arranged directly in direct mechanical and/or electrical contact on another layer. One layer may also be arranged indirectly on another layer, in which case further layers may then be present between the indicated layers. Such layers can serve to further improve the functionality and thus the efficiency of the electronic component. The metal layer is very generally arranged directly on the electrode growth layer.

The combination of electrode growth layer and metal layer provided in the electronic component makes it possible to provide a very thin and at the same time very conductive contact, which—if necessary—may additionally also be embodied as highly transparent.

In various configurations, forming the layer structure may include forming the additional electrode on a substrate, and forming the organic functional layer on the additional electrode. The electrode growth layer may be formed on the organic functional layer.

The electronic component may be formed as an organic light emitting diode.

Furthermore, the metal layer may be applied temporally directly after the electrode growth layer.

In various embodiments, a good transparency, conductivity and long-term stability of OLEDs having a transparent metallic top electrode is achieved by applying a growth layer (also designated as intermediate layer hereinafter) below an electrode (also designated as top contact) with the aid of atomic layer deposition (ALD). The intermediate layer can consist, for example, of conductive metal oxides such as zinc oxide or aluminum-doped zinc oxide, but thin layers composed of nonconductive oxides such as aluminum oxide, titanium oxide, hafnium oxide, lanthanum oxide and zirconium oxide are also provided in various embodiments.

An “organic functional layer” may contain emitter layers, for example with fluorescent and/or phosphorescent emitters.

Examples of emitter materials which may be used in the electronic component in accordance with various embodiments or the radiation emitting device in accordance with various embodiments include organic or organometallic compounds, such as derivatives of polyfluorene, polythiophene and polyphenylene (e.g. 2- or 2,5-substituted poly-p-phenylene vinylene), and metal complexes, for example iridium complexes such as blue phosphorescent FIrPic (Bis(3,5-difluoro-2-(2-pyridyl)phenyl-(2-carboxypyridyl)iridium III), green phosphorescent Ir(ppy)₃ (Tris(2-phenylpyridine)iridium III), red phosphorescent Ru (dtb-bpy)₃*2(PF₆) (Tris[4,4′-di-tert-butyl-(2,2′)-bipyridine]ruthenium(III) complex) and blue fluorescent DPAVBi (4,4-Bis[4-(di-p-tolyamino)styryl]biphenyl), green fluorescent TTPA (9,10-Bis[N,N-di-(p-tolyl)amino]anthracene) and red fluorescent DCM2 (4-dicyanomethylene)-2-methyl-6-julolidyl-9-enyl-4H-pyrane) as non-polymeric emitters. Such non-polymeric emitters can be deposited by means of thermal evaporation, for example.

Furthermore, it is possible to use polymer emitters, which may be deposited, in particular, by means of wet-chemical methods such as spin coating, for example.

The emitter materials may be embedded in a matrix material in a suitable manner.

The emitter materials of the emitter layers of the electronic component may be selected, for example, such that the electronic component emits white light. The emitter layer may include a plurality of emitter materials that emit in different colors (for example blue and yellow, or blue, green and red); alternatively, the emitter layer may also be constructed from a plurality of partial layers, such as a blue fluorescent emitter layer, a green phosphorescent emitter layer and a red phosphorescent emitter layer. By mixing the different colors, the emission of light having a white color impression can result. Alternatively, provision may also be made for arranging a converter material in the beam path of the primary emission generated by said layers, which converter material at least partly absorbs the primary radiation and emits a secondary radiation having a different wavelength, such that a white color impression results from a (not yet white) primary radiation by virtue of the combination of primary and secondary radiation.

The electronic component may generally include further organic functional layers that serve to further improve the functionality and thus the efficiency of the electronic component.

By way of example, organic functional layers can be selected which serve to improve the functionality and the efficiency of the electrode and/or of the additional electrode and of the charge carrier and exciton transport.

The electronic component may be embodied as a “bottom emitter” and/or a “top emitter”.

In one embodiment, the growth layer is arranged between the organic functional layer and the additional electrode as growth electrode.

The arrangement of the electrode growth layer and of the electrode may form a transparent top contact for a top emitter.

In another embodiment, the electrode growth layer is arranged between the substrate and the first electrode as growth electrode. The electrode may be an anode in this case. The substrate can preferably be a transparent substrate such as glass, quartz, sapphire, plastic film and the like.

The arrangement of the electrode growth layer and of the growth electrode can form a transparent substrate contact for a bottom emitter.

It very generally holds true that, in the case of a top emitter or a bottom emitter, one electrode of the radiation emitting device in the form of the growth electrode in accordance with various embodiments may be embodied as transparent and the other electrode as reflective. As an alternative thereto, both electrodes may also be embodied as transparent.

The metal layer of the growth electrode can form, for example, a transparent thin-film contact.

The term “bottom emitter” as used herein denotes an embodiment which is embodied as transparent toward the substrate side of the electronic component. By way of example, for this purpose at least the substrate, the electrode and the electrode growth layer arranged between the substrate and the electrode may be embodied as transparent. An electronic component embodied as a bottom emitter may accordingly emit, for example, radiation generated in the organic functional layers on the substrate side of the electronic component.

As an alternative or in addition thereto, in accordance with various embodiments, the electronic component may be embodied as a “top emitter”.

The term “top emitter” as used herein denotes, for example, an embodiment which is embodied as transparent toward the side of the second electrode of the electronic component. In particular, for this purpose the electrode growth layer and the second electrode may be embodied as transparent. An electronic component embodied as a top emitter can accordingly emit, for example, radiation generated in the organic functional layers on the side of the additional electrode of the electronic component.

An electronic component configured as a top emitter in accordance with various embodiments, in which the electrode growth layer and the metal layer are provided as top contact, can advantageously have high coupling-out of light and a very low angle dependence of the radiance. The radiation emitting device in accordance with various embodiments can advantageously be used for lighting systems, such as, for example, room luminaires.

A combination of bottom emitter and top emitter is likewise provided in various embodiments. In the case of such an embodiment, the electronic component is generally able to emit the light generated in the organic functional layers in both directions—that is to say both toward the substrate side and toward the side of the second electrode.

In a further embodiment, at least one third electrode is arranged between the electrode and the additional electrode, and the electrode growth layer is arranged on that side of the third electrode which faces the substrate.

The “third electrode” may function as an intermediate contact. It can serve to increase charge transport through the layers of the electronic component and thus to improve the efficiency of the electronic component. The third electrode may be configured as an ambipolar layer; it may be configured as a cathode or anode.

The arrangement of the electrode growth layer and of the growth electrode in accordance with one embodiment then forms a transparent intermediate contact.

The third electrode is electrically contact-connected just like the electrode and the additional electrode.

In one development of the electronic component, an emitter layer and one or more further organic functional layers are contained as organic functional layers. The further organic functional layers may be selected from the group consisting of hole injection layers, hole transport layers, hole blocking layers, electron injection layers, electron transport layers and electron blocking layers.

Suitable functional layers and suitable organic functional layers are known per se to the person skilled in the art. The (organic) functional layers may preferably be applied by means of thermal evaporation. The further (organic) functional layers can advantageously improve the functionality and/or efficiency of the electronic component.

In a further embodiment, the electronic component is embodied as an organic light emitting diode (OLED).

In one development of the electronic component, the electronic component has a substantially Lambertian emission characteristic. The term “Lambertian emission characteristic” as used herein denotes the ideal emission behavior of a so-called Lambert emitter. A “substantially” Lambertian emission characteristic as designated herein in this case means, in particular, that the emission characteristic, which is calculated according to the formula

I(θ)=I₀·cos θ

and in which I₀ indicates the intensity relative to a surface normal and θ indicates the angle with respect to the surface normal, for a given angle, in particular at an angle of between −70° and +70°, for each given angle θ, deviates by not more than 10% from the intensity in accordance with the above-mentioned formula, that is to say I(θ)=I₀·cos θ·x, wherein x=90%-110%.

In this way, it may be possible to achieve a radiance or luminance of the electronic component that is constant to all directions, such that the electronic component appears equally bright in all directions. The brightness of the electronic component can advantageously not change even when said component is tilted relatively to the viewing direction.

In a further embodiment, the transparency of the electronic component is greater than or equal to 60%. By way of example, the transparency can be greater than or equal to 65%. The transparency is measured by means of intensity measurements by predefined wavelength ranges being scanned and the quantity of light that passes through the radiation emitting device being detected.

The term “transparency” as used herein denotes the ability of the individual layers of the electronic component in accordance with various embodiments to transmit electromagnetic waves and in particular visible light.

The transparency of the electronic component in accordance with various embodiments is very generally more than 60%, preferably more than 65%, at least for at least one specific wavelength. By way of example, the transparency for at least one wavelength in a wavelength range of approximately 400 nm to approximately 650 nm can be more than 60% and for example more than 65%.

The arrangement of the electrode growth layer and of the growth electrode in accordance with various embodiments can thus provide a transparency that is improved by comparison with the prior art in conjunction with sufficient energization.

In a further embodiment, the metal layer is applied temporally directly after the electrode growth layer. The term “applied temporally directly” or preferably “applied in succession”, as used herein, means that the metal layer is deposited temporally directly after the electrode growth layer during the process for producing the electronic component, e.g. without a change of reactor or not later than one day after the deposition of the electrode growth layer. The direct deposition of the metal layer on the electrode growth layer can prevent ageing of the electrode growth layer; by way of example, no or only little ageing of the e.g. amorphous surface occurs, as a result of which it is possible to maintain its amorphous appearance for the suitable deposition of the metal layer.

The electronic component in accordance with various embodiments may furthermore include further functional layers, such as, for example, antireflection layers, scattering layers, layers for color conversion of light and/or mechanical protective layers. Such layers can be arranged, for example, on the metal layer of the growth electrode. The functional layers can be deposited by means of thermal evaporation, for example. These layers may further improve the function and efficiency of the radiation emitting device.

In various embodiments, the electronic component includes a substrate, at least one first electrode arranged on the substrate, and an (electrode) growth layer on that side of the electrode which faces the substrate. The electrode arranged on the growth layer includes, for example, a metal layer having a thickness of less than or equal to 30 nm and the growth layer has a thickness of less than or equal to 10 nm.

A “substrate” as used herein may include, for example, a substrate such as is conventionally used in the prior art for an electronic component. The substrate can be a transparent substrate. However, it may also be a nontransparent substrate. By way of example, the substrate may include glass, quartz, sapphire, plastic films, metal, metal films, silicon wafers or some other suitable substrate material. A metal substrate will very generally be used only when the growth layer is not arranged directly thereon. The substrate is understood to mean, in particular, the layer on which all other layers are subsequently applied during the production of the electronic component. Such subsequent layers can be layers required for radiation emission e.g. in an optical electronic component or a radiation emitting device.

The “first electrode” may be an anode or a cathode.

The term “growth layer” as used herein denotes a layer on which an electrode having a metal layer (also designated as growth electrode hereinafter) is arranged.

The growth layer may be formed from a material or include a material selected from transparent conductive oxides such as, for example, metal oxides, such as zinc oxide, tin oxide, cadmium oxide, titanium oxide, indium oxide or indium-doped tin oxide (ITO), aluminum-doped zinc oxide (AZO), Zn₂SnO₄, CdSnO₃, ZnSnO₃, MgIn₂O₄, GalnO₃, Zn₂In₂O₅ or In₄Sn₃O₁₂ or mixtures of different transparent conductive oxides.

The contribution of the growth layer to the lateral current conduction is usually negligible.

Since the growth layer is a very thin layer, it need not necessarily be conductive. The growth layer may therefore likewise include dielectric oxides such as Al₂O₃, WO₃, Re₂O₇ and the like or be formed therefrom.

The growth layer can be applied by means of physical vapor deposition, for example evaporation methods, such as thermal evaporation, electron beam evaporation, laser beam evaporation, arc evaporation, molecular beam epitaxy and the like, sputtering, such as ion beam assisted deposition and the like, or ion plating, chemical vapor deposition, such as plasma enhanced chemical vapor deposition and the like, or atomic layer deposition and the like.

The surface of the growth layer can be prepared or designed in a suitable manner, for example, in order to make possible a uniform or homogeneous deposition of a metal layer to be deposited thereon. In one embodiment, the surface of the growth layer can have an amorphous or substantially amorphous structure or an amorphous or substantially amorphous surface. A fully amorphous structure can be confirmed for example by means of X-ray diffraction (XRD diffractograms) (no discrete Bragg reflections are obtained).

The term “metal layer” as used herein denotes a layer formed substantially or completely from metal. The metal layer is arranged directly on the growth layer. It can be grown epitaxially on the growth layer. The thickness of the metal layer is less than or equal to 30 nm, for example between 9 nm and 10 nm.

The metal layer may have a thickness of less than or equal to 15 nm, in particular of less than or equal to 12 nm. In embodiments in which, in particular, the transparency of the metal layer is of importance, the thickness of the metal layer may be, for example, less than or equal to 14 nm, in particular less than or equal to 11 nm. By way of example, the thickness of a metal layer including an Ag layer or a layer composed of an Ag alloy (e.g. a layer composed of an Ag—Sm alloy) may be less than or equal to 14 nm, in particular less than or equal to 11 nm, for example between approximately 9 nm and approximately 10 nm.

The growth electrode may consist of the metal layer or include one or further layers or functional layers.

The metal layer of the growth electrode includes, for example, at least one metal selected from the group consisting of aluminum, barium, indium, silver, gold, magnesium, calcium and lithium and combinations thereof. The metal layer can alternatively consist of one of the abovementioned metals or a compound including one of said metals or composed of a plurality of said metals, in particular an alloy.

The growth electrode can be used in transparent and non-transparent electronic, optical or electro-optical components. The growth electrode arranged on the growth layer may be used as a top contact, substrate contact and/or intermediate contact.

The term “layer” as used herein may denote an individual layer or a layer sequence composed of a plurality of thin layers. By way of example, the functional layers, for example organic functional layers, can be formed from a plurality of layers. The metal layer and the growth layer are usually single-layered.

The term “arranged one on top of another” as used herein means that one layer is arranged directly in direct mechanical and/or electrical contact on another layer. One layer can also be arranged indirectly on another layer, in which case further layers can then be present between the indicated layers. Such layers can serve to further improve the functionality and thus the efficiency of the electronic component. The metal layer is very generally arranged directly on the growth layer.

The combination of growth layer and metal layer provided in the electronic component in accordance with various embodiments makes it possible to provide a very thin and at the same time very conductive contact, which—if necessary—can additionally also be embodied as highly transparent.

In one development of the electronic component in accordance with various embodiments, the growth layer has, for example, a thickness of 1 nm to 8 nm. The growth layer has, for example, a thickness of 3 nm to 3.5 nm. In specific embodiments, a thickness of greater than or equal to 1.5 nm can be advantageous. The thickness of the growth layer can be less than or equal to 7 nm, for example, in specific embodiments.

In one embodiment of the electronic component in accordance with various embodiments, the growth layer is selected from a layer composed of indium-doped tin oxide (ITO) and a layer composed of aluminum-doped zinc oxide (AZO).

In one development of the electronic component, the metal layer has a thickness homogeneity of ±10%, often even ±5%.

The term “thickness homogeneity” as used herein means that the metal layer can have a thickness that is virtually constant over its substantial or complete length, i.e. a thickness having a maximum deviation of e.g. ±10%. This can be achieved, for example, in particular by means of the (thin) growth layer arranged below the metal layer.

The maximum thickness of a “30 nm thick” metal layer can therefore be, for example, a maximum of 33 nm, and the maximum thickness of a “12 nm thick” metal layer can be, for example, a maximum of 13.2 nm.

In a further embodiment, the sheet resistance of the growth electrode on the growth layer is less than or equal to 6Ω/□. The sheet resistance can be, for example, less than or equal to 5Ω/□. By way of example, the sheet resistance can be in a range of 4Ω/□ and 5Ω/□.

The term “sheet resistance” as used herein denotes the isotropic resistivity of a layer relative to the thickness thereof. The sheet resistance can be measured, for example, with the aid of the four-point method. Alternatively, a sheet resistance can also be measured by the special Van-Der-Pauw method.

The sheet resistance can thus be less than has been customary hitherto in the prior art with comparable electrode layers deposited on a different substrate than the growth layer in accordance with various embodiments. The arrangement in accordance with various embodiments may make it possible to achieve a uniform energization of the thin growth electrode—in optoelectronic components with sufficient transparency.

In a further embodiment, the electronic component in accordance with various embodiments is an organic electronic component and furthermore includes a second electrode and at least one organic functional layer arranged between the first electrode and the second electrode.

The organic electronic component is e.g. an optoelectronic component or a radiation emitting device.

The “first electrode” can be an anode. It may have hole-injecting functions.

The “second electrode” may be a cathode.

The first electrode and the second electrode are electrically contact-connected in a suitable manner.

The first electrode and/or the second electrode arranged on the growth layer are/is—as indicated above—also designated as growth electrode. The growth electrode can be provided as an anode or cathode or form part thereof.

The electrode which is not arranged on an growth layer may be formed from a material or include a material selected from metals such as aluminum, barium, indium, silver, gold, magnesium, calcium and lithium and combinations thereof or a compound thereof, in particular an alloy, and transparent conductive oxides such as, for example, metal oxides, such as zinc oxide, tin oxide, cadmium oxide, titanium oxide, indium oxide or indium-doped tin oxide (ITO), aluminum-doped zinc oxide (AZO), Zn₂SnO₄, CdSnO₃, ZnSnO₃, MgIn₂O₄, GalnO₃, Zn₂In₂O₅ or In₄Sn₃O₁₂ or mixtures of different transparent conductive oxides.

An “organic functional layer” can contain emitter layers, for example with fluorescent and/or phosphorescent emitters.

Examples of emitter materials which can be used in the electronic component in accordance with various embodiments or the radiation emitting device in accordance with various embodiments include organic or organometallic compounds, such as derivatives of polyfluorene, polythiophene and polyphenylene (e.g. 2- or 2,5-substituted poly-p-phenylene vinylene), and metal complexes, for example iridium complexes such as blue phosphorescent FIrPic (Bis(3,5-difluoro-2-(2-pyridyl)phenyl-(2-carboxypyridyl)iridium III), green phosphorescent Ir(ppy)₃ (Tris(2-phenylpyridine)iridium III), red phosphorescent Ru (dtb-bpy)3*2(PF6) (Tris[4,4′-di-tert-butyl-(2,2′)-bipyridine]ruthenium(III) complex) and blue fluorescent DPAVBi (4,4-Bis[4-(di-p-tolyamino)styryl]biphenyl), green fluorescent TTPA (9,10-Bis[N,N-di-(p-tolyl)amino]anthracene) and red fluorescent DCM2 (4-dicyanomethylene)-2-methyl-6-julolidyl-9-enyl-4H-pyrane) as non-polymeric emitters. Such non-polymeric emitters can be deposited by means of thermal evaporation, for example. Furthermore, it is possible to use polymer emitters, which can be deposited, for example, by means of wet-chemical methods such as spin coating, for example.

The emitter materials may be embedded in a matrix material in a suitable manner.

The emitter materials of the emitter layers of the electronic component can be selected, for example, such that the electronic component emits white light. The emitter layer may include a plurality of emitter materials that emit in different colors (for example blue and yellow, or blue, green and red); alternatively, the emitter layer can also be constructed from a plurality of partial layers, such as a blue fluorescent emitter layer, a green phosphorescent emitter layer and a red phosphorescent emitter layer. By mixing the different colors, the emission of light having a white color impression can result. Alternatively, provision can also be made for arranging a converter material in the beam path of the primary emission generated by said layers, which converter material at least partly absorbs the primary radiation and emits a secondary radiation having a different wavelength, such that a white color impression results from a (not yet white) primary radiation by virtue of the combination of primary and secondary radiation.

The electronic component may generally include further organic functional layers that serve to further improve the functionality and thus the efficiency of the electronic component.

By way of example, organic functional layers can be selected which serve to improve the functionality and the efficiency of the first electrode and/or of the second electrode and of the charge carrier and exciton transport.

The electronic component can be embodied as a “bottom emitter” and/or a “top emitter”.

In one embodiment, the growth layer is arranged between the organic functional layer and the second electrode as growth electrode.

The second electrode can be a cathode.

The arrangement of the growth layer and of the growth electrode can form a transparent top contact for a top emitter.

In another embodiment, the growth layer is arranged between the substrate and the first electrode as growth electrode. The first electrode can be an anode in this case. The substrate can preferably be a transparent substrate such as glass, quartz, sapphire, plastic film and the like.

The arrangement of the growth layer and of the growth electrode can form a transparent substrate contact for a bottom emitter.

It very generally holds true that, in the case of a top emitter or a bottom emitter, one electrode of the radiation emitting device in the form of the growth electrode in accordance with various embodiments can be embodied as transparent and the other electrode as reflective. As an alternative thereto, both electrodes can also be embodied as transparent.

The metal layer of the growth electrode therefore forms, for example, a transparent thin-film contact.

The term “bottom emitter” as used herein denotes an embodiment which is embodied as transparent toward the substrate side of the electronic component. By way of example, for this purpose at least the substrate, the first electrode and the growth layer arranged between the substrate and the first electrode can be embodied as transparent. An electronic component embodied as a bottom emitter can accordingly emit, for example, radiation generated in the organic functional layers on the substrate side of the electronic component.

As an alternative or in addition thereto, in accordance with various embodiments, the electronic component can be embodied as a “top emitter”.

The term “top emitter” as used herein denotes an embodiment which is embodied as transparent toward the side of the second electrode of the electronic component. For example, for this purpose the growth layer and the second electrode can be embodied as transparent. An electronic component embodied as a top emitter can accordingly emit, for example, radiation generated in the organic functional layers on the side of the second electrode of the electronic component.

An electronic component configured as a top emitter in accordance with various embodiments, in which the growth layer and the metal layer are provided as top contact, can have high coupling-out of light and a very low angle dependence of the radiance. The radiation emitting device in accordance with various embodiments can be used for lighting systems, such as, for example, room luminaires.

A combination of bottom emitter and top emitter is provided in the same way. In the case of such an embodiment, the electronic component is generally able to emit the light generated in the organic functional layers in both directions—that is to say both toward the substrate side and toward the side of the second electrode.

In a further embodiment, at least one third electrode is arranged between the first electrode and the second electrode, and the growth layer is arranged on that side of the third electrode which faces the substrate.

The “third electrode” can function as an intermediate contact. It can serve to increase charge transport through the layers of the electronic component and thus to improve the efficiency of the electronic component. The third electrode can be configured as an ambipolar layer; it can be configured as a cathode or anode.

The arrangement of the growth layer and of the growth electrode of the present embodiment then forms a transparent intermediate contact.

The third electrode is electrically contact-connected just like the first electrode and the second electrode.

In one development of the electronic component, an emitter layer and one or more further organic functional layers are contained as organic functional layers. The further organic functional layers can be selected from the group consisting of hole injection layers, hole transport layers, hole blocking layers, electron injection layers, electron transport layers and electron blocking layers.

Suitable functional layers and suitable organic functional layers are known per se to the person skilled in the art. The (organic) functional layers can preferably be applied by means of thermal evaporation. The further (organic) functional layers can advantageously improve the functionality and/or efficiency of the electronic component.

In a further embodiment, the electronic component is embodied as an organic light emitting diode (OLED).

In one development of the electronic component, the electronic component has a substantially Lambertian emission characteristic.

The term “Lambertian emission characteristic” as used herein denotes the ideal emission behavior of a so-called Lambert emitter. A “substantially” Lambertian emission characteristic as designated herein in this case means, in particular, that the emission characteristic, which is calculated according to the formula

I(θ)=I0·cos θ

and in which I0 indicates the intensity relative to a surface normal and θ indicates the angle with respect to the surface normal, for a given angle, in particular at an angle of between −70° and +70°, for each given angle θ, deviates by not more than 10% from the intensity in accordance with the above-mentioned formula, that is to say I(θ)=I0·cos θ·x, wherein x=90%-110%.

In this way, it may be possible to achieve a radiance or luminance of the electronic component, in accordance with various embodiments, that is constant to all directions, such that the electronic component appears equally bright in all directions. The brightness of the electronic component can not change even when said component is tilted relative to the viewing direction.

In a further embodiment, the transparency of the electronic component is greater than or equal to 60%.

By way of example, the transparency can be greater than or equal to 65%. The transparency is measured by means of intensity measurements by predefined wavelength ranges being scanned and the quantity of light that passes through the radiation emitting device being detected.

The term “transparency” as used herein denotes the ability of the individual layers of the electronic component in accordance with various embodiments to transmit electromagnetic waves and in particular visible light.

The transparency of the electronic component in accordance with various embodiments is very generally more than 60%, preferably more than 65%, at least for at least one specific wavelength. By way of example, the transparency for at least one wavelength in a wavelength range of approximately 400 nm to approximately 650 nm can be more than 60% and preferably more than 65%.

The arrangement of the growth layer and of the growth electrode in accordance with various embodiments can thus provide a transparency that is improved by comparison with the prior art in conjunction with sufficient energization.

In a further embodiment, the growth layer is applied by means of sputtering. The growth layer can be applied for example by means of facing target sputtering or hollow cathode sputtering.

The term “facing target sputtering” as used herein denotes a single-stage process by mean of which closed epitaxial layers can be obtained.

The term “hollow cathode sputtering” as used herein denotes a sputtering method using a hollow cathode sputtering installation having a hollow cathode composed of target material. In comparison with the sputtering methods that usually proceed at a pressure of less than 1 Pa, improved properties of the growth layer can be obtained in the case of hollow cathode sputtering since practically no bombardment of the layer with energetic neutral particles reflected from the target takes place.

The growth layer deposited by means of facing target sputtering or hollow cathode sputtering very generally has a substantially amorphous appearance or a substantially amorphous surface. A thin metal layer can be deposited particularly well on such an amorphous surface, in order in this way to provide a transparent contact for an electronic component of the present invention. Layers applied by means of sputtering very generally have inclusions containing the process gas used for sputtering (e.g. argon).

By using a sputtering method for applying the growth layer, it is possible to avoid deposition of non-stoichiometric layers which can result from thermal evaporation at excessively high temperatures, in which case the damage to the underlying layers that often occurs in the case of reactive sputtering as the coating time increases, owing to various influences from the sputtering plasma, can be avoided on account of the very thin growth layer provided in accordance with various embodiments.

By applying the growth layer by means of sputtering, it is thus advantageously possible to achieve damage-free and/or stoichiometric application of the growth layer. This can be advantageous for example when coating sensitive structures, such as are present for example in the case of organic light emitting diodes.

In a further embodiment of the present invention, the metal layer is applied temporally directly after the growth layer.

The term “applied temporally directly” or preferably “applied in succession”, as used herein, means that the metal layer is deposited temporally directly after the growth layer during the process for producing the electronic component, e.g. without a change of reactor or not later than one day after the deposition of the growth layer.

The direct deposition of the metal layer on the growth layer can prevent ageing of the growth layer; by way of example, no or only little ageing of the e.g. amorphous surface occurs, as a result of which it is possible to maintain its amorphous appearance for the suitable deposition of the metal layer.

The electronic component in accordance with various embodiments may furthermore include further functional layers, such as, for example, antireflection layers, scattering layers, layers for color conversion of light and/or mechanical protective layers. Such layers can be arranged, for example, on the metal layer of the growth electrode. The functional layers can preferably be deposited by means of thermal evaporation. These layers can further improve the function and efficiency of the radiation emitting device.

An electrical contact in accordance with various embodiments is suitable for use in or with an electronic component.

The electrical contact in accordance with various embodiments includes a substrate, at least one first electrode arranged on the substrate, and a growth layer on that side of the electrode which faces the substrate, wherein the electrode arranged on the growth layer includes a metal layer having a thickness of less than or equal to 30 nm, and the growth layer has a thickness of less than or equal to 10 nm.

Since substantially all advantages which can be obtained with the electronic contact in accordance with various embodiments can already be obtained with the electrical contact in accordance with various embodiments, with regard to further configurations, in order to avoid repetition, reference is made to the above explanations in this respect.

By depositing the metal layer on the thin growth layer, it is possible for the electrode growth electrode to be embodied uniformly, smoothly and substantially homogeneously. For this reason, for example, said electrode growth electrode can be made significantly thinner than in accordance with the prior art. It is thus possible—unlike with the transparent contacts composed of either transparent conductive oxides having a conductivity of greater than 15Ω/□ or thin metal layers having a thickness of at least 20 nm as used in the prior art—to achieve a high transparency and good energization even in large-area applications.

In the electronic components in accordance with various embodiments in which transparency is essential, it is thus possible to make a compromise between transparency and conductivity of transparent metallic contacts since the metal layer deposited on the electrode growth layer can be formed in a sufficiently thin, smooth and closed manner in order thus to provide, for example, a sufficient conductivity and at the same time an excellent transparency.

### BRIEF DESCRIPTION OF THE DRAWINGS

In the drawings, like reference characters generally refer to the same parts throughout the different views. The drawings are not necessarily to scale, emphasis instead generally being replaced upon illustrating the principles of the invention. In the following description, various embodiments of the invention are described with reference to the following drawings, in which:

FIG. 1 shows a flow chart illustrating a method for producing an electronic component in accordance with one embodiment;

FIGS. 2A to 2E show schematically simplified sectional views of an electronic component in accordance with one embodiment in a partial section at different points in time during the production of the electronic component;

FIGS. 3A to 3E show schematically simplified side views of an electronic component in accordance with another embodiment in a partial section at different points in time during the production of the electronic component;

FIG. 4 shows a schematically simplified side view of an electronic component in accordance with another embodiment in a partial section;

FIG. 5 shows a schematically simplified side view of an electronic component in accordance with another embodiment in a partial section;

FIG. 6 shows a schematically simplified side view of an electronic component in accordance with another embodiment in a partial section;

FIG. 7 shows an SEM micrograph of a thin silver layer deposited on a glass substrate;

FIG. 8 shows an SEM micrograph of a thin silver layer deposited on a conventional organic system support;

FIG. 9 shows an SEM micrograph of a thin silver layer deposited according to the invention on an ITO growth layer;

FIG. 10 shows a graph showing the result of a measurement of the transparency of the silver layers from FIG. 4 to FIG. 6; and

FIG. 11 shows emission characteristics of an electro-optical component in accordance with one embodiment.

### DETAILED DESCRIPTION

In the following detailed description, reference is made to the accompanying drawings, which form part of this description and show for illustrative purposes specific embodiments in which the invention can be implemented. In this regard, direction terminology such as, for instance, “at the top”, “at the bottom”, “at the front”, “at the back”, “front”, “rear” etc. is used with reference to the orientation of the figure(s) described. Since components of embodiments can be positioned in a number of different orientations, the direction terminology is used for illustrative purposes and is not restrictive in any way whatsoever. It goes without saying that other embodiments can be used and structural or logical changes can be made without departing from the scope of protection of the present invention. It goes without saying that the features of the different embodiments described herein can be combined with one another, unless specifically indicated otherwise. The following detailed description should therefore not be interpreted in a restrictive sense, and the scope of protection of the present invention is defined by the enclosed claims.

In the context of this description, the terms “connected” and “coupled” are used to describe both a direct and an indirect connection, and a direct or indirect coupling. In the figures, identical or similar elements are provided with identical reference signs, in so far as this is expedient.

Various embodiments describe an optimization of transparent metal electrodes on organic optoelectronic components with regard to their transparency, conductivity and long-term stability by the insertion of one or a plurality of thin transparent metal oxide layers with the aid of atomic layer deposition (also designated as atomic layer epitaxy).

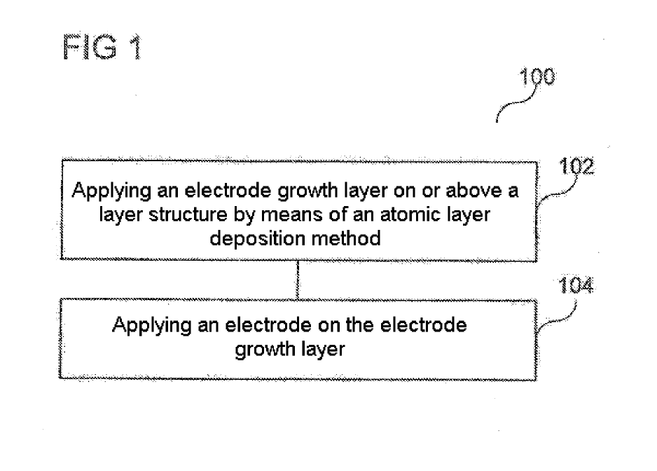

FIG. 1 shows a flow chart 100 illustrating a method for producing an electronic component in accordance with one embodiment. In accordance with various embodiments, in 102 an electrode growth layer can be applied on or above a layer structure by means of an atomic layer deposition method. Furthermore, in 104 an electrode (also designated as growth electrode) can be applied on the electrode growth layer.

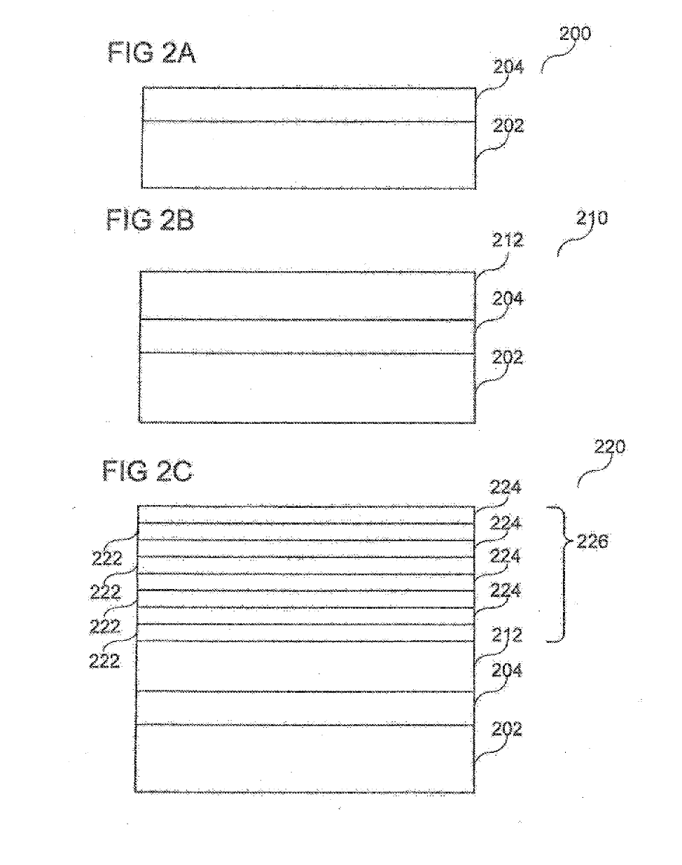

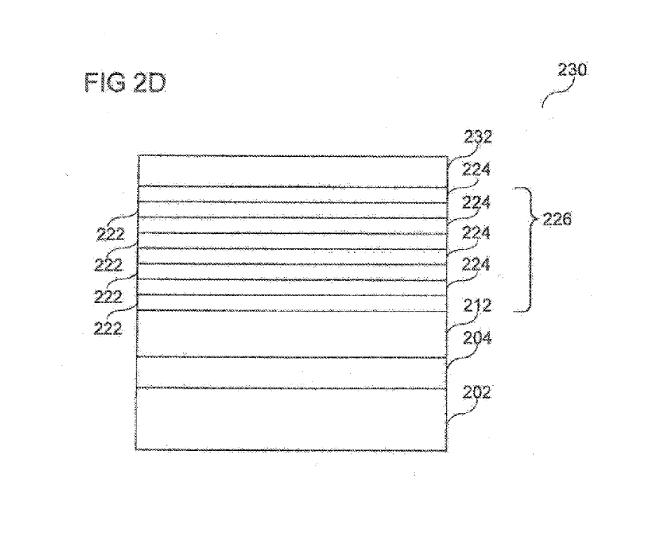

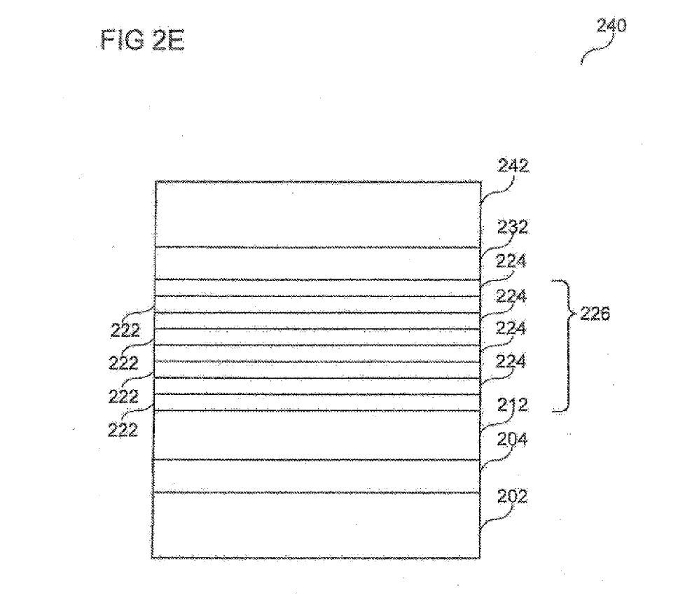

FIGS. 2A to 2E show schematically simplified side views of an electronic component, for example of an organic light emitting diode (OLED), in accordance with one embodiment in a partial section at different points in time during the production of the electronic component.

As is shown in a first partial structure 200 in FIG. 2A, a first electrode 204, also designated as bottom electrode 204 hereinafter, is applied, for example deposited, onto a substrate 202. The substrate 202 can be a transparent substrate 202. However, the substrate 202 can also be a nontransparent substrate 202. By way of example, the substrate may include glass, quartz, sapphire, plastic film(s), metal, metal film(s), silicon wafers or some other suitable substrate material. A metal substrate can be used, for example, if the electrode growth layer, as will be explained in even greater detail below, is not arranged directly thereon. In various embodiments, the bottom electrode 204 can be an anode, for example, and can have been formed or be formed from indium-doped tin oxide (ITO), for example. In various embodiments, the substrate 202 and/or the first electrode 204 can be embodied as transparent.

In various embodiments, the first electrode 204 can be applied by means of sputtering or by means of thermal evaporation. In various embodiments, the first electrode 204 can have a layer thickness in a range of approximately 5 nm to approximately 30 nm, for example a layer thickness in a range of approximately 10 nm to approximately 20 nm.

As is shown in a second partial structure 210 in FIG. 2B, one or a plurality of organic functional layers 212 for charge transport and for generating light, such as, for example, a fluorescent and/or a phosphorescent emitter layer, is or are applied to the first partial structure 200.

Examples of emitter materials which can be provided in the electronic component, for example an OLED, in accordance with various embodiments include organic or organometallic compounds, such as derivatives of polyfluorene, polythiophene and polyphenylene (e.g. 2- or 2,5-substituted poly-p-phenylene vinylene), and metal complexes, for example iridium complexes such as blue phosphorescent FIrPic (Bis(3,5-difluoro-2-(2-pyridyl)phenyl-(2-carboxypyridyl)iridium III), green phosphorescent Ir(ppy)₃ (Tris(2-phenylpyridine)iridium III), red phosphorescent Ru (dtb-bpy)₃*2(PF₆) (Tris[4,4′-di-tert-butyl-(2,2′)-bipyridine]ruthenium(III) complex) and blue fluorescent DPAVBi (4,4-Bis[4-(di-p-tolyamino)styryl]biphenyl), green fluorescent TTPA (9,10-Bis[N,N-di-(p-tolyl)amino]anthracene) and red fluorescent DCM2 (4-dicyanomethylene)-2-methyl-6-julolidyl-9-enyl-4H-pyrane) as non-polymeric emitters. Such non-polymeric emitters can be deposited by means of thermal evaporation, for example. Furthermore, it is possible to use polymer emitters, which can be deposited, in particular, by means of wet-chemical methods such as spin coating, for example.

The emitter materials can be embedded in a matrix material in a suitable manner.

The emitter materials of the emitter layers of the electronic component can be selected, for example, such that the electronic component emits white light. The emitter layer may include a plurality of emitter materials that emit in different colors (for example blue and yellow, or blue, green and red); alternatively, the emitter layer can also be constructed from a plurality of partial layers, such as a blue fluorescent emitter layer, a green phosphorescent emitter layer and a red phosphorescent emitter layer. By mixing the different colors, the emission of light having a white color impression can result. Alternatively, provision can also be made for arranging a converter material in the beam path of the primary emission generated by said layers, which converter material at least partly absorbs the primary radiation and emits a secondary radiation having a different wavelength, such that a white color impression results from a (not yet white) primary radiation by virtue of the combination of primary and secondary radiation.

It is possible to provide further organic functional layers which serve, for example, to further improve the functionality and thus the efficiency of the electronic component.

It is pointed out that, in alternative embodiments, any suitable form of light emitting functional layers, for example organic functional layers, can be provided and the invention is not restricted to a specific type of functional layer(s).

As is shown in a third partial structure 220 in FIG. 2C, one or a plurality of transparent intermediate electrodes (also designated as one or a plurality of electrode growth layer(s) hereinafter) is or are applied to the second partial structure 210. In various embodiments, the at least one intermediate layer is applied by means of an atomic layer deposition method. The at least one intermediate layer or the intermediate layer stack 226 formed by a plurality of intermediate layers can have a layer thickness in the nanometers range, for example a layer thickness in a range of approximately 0.1 nm to approximately 200 nm, for example a layer thickness in a range of approximately 1 nm to approximately 8 nm, for example a layer thickness in a range of approximately 3 nm to approximately 3.5 nm, for example a layer thickness of greater than or equal to 1.5 nm. The layer thickness of the electrode growth layer(s) can be in each case or overall in various configurations for example less than or equal to 7 nm. FIG. 2C illustrates an intermediate layer stack 226 having a plurality of partial intermediate layers 222, 224 which are or have been applied in each case by means of an atomic layer deposition method. In various embodiments, a plurality of different materials, for example two different materials, can be provided, wherein each material forms a respective partial intermediate layer 222, 224. In various embodiments, the respective partial intermediate layers 222, 224 can be deposited from respectively alternately deposited different materials by means of an atomic layer deposition method. Thus, by way of example, a first partial intermediate layer 222 can be deposited from a first material (for example an oxide, nitride, carbide or some other material suitable for deposition by means of an atomic layer deposition method, for example zinc oxide), with a layer thickness of a few nanometers (for example onto the free surface of the organic functional layer(s) 212), for example with a layer thickness in a range of approximately 2 nm to approximately 8 nm, for example with a layer thickness in a range of approximately 3 nm to approximately 7 nm, for example with a layer thickness in a range of approximately 4 nm to approximately 6 nm, for example with a layer thickness of approximately 5 nm. Furthermore, by way of example, it is possible to deposit onto the first partial intermediate layer 222 a second partial intermediate layer 224 composed of a second material (for example an oxide, nitride, carbide or some other material suitable for deposition by means of an atomic layer deposition method, for example zinc oxide), which differs from the first material, for example, with a layer thickness of a few nanometers, for example with a layer thickness in a range of approximately 0.5 nm to approximately 8 nm, for example with a layer thickness in a range of approximately 1 nm to approximately 5 nm, for example with a layer thickness in a range of approximately 1.5 nm to approximately 3 nm, for example with a layer thickness of approximately 2 nm. It is then possible once again to deposit a further first partial intermediate layer 222 onto the second partial intermediate layer 224, a further second partial intermediate layer 224 onto the further first partial intermediate layer 222, etc. The formation of a plurality of partial intermediate layer stacks (wherein each partial intermediate layer stack may include a first partial intermediate layer 222 and a second partial intermediate layer 224), can be repeated as often as desired, in principle; by way of example, it is possible to provide two, three, four, five, six, seven or more partial intermediate layer stacks (depending on the desired total thickness of the intermediate layer stack). The atomic layer deposition method is carried out repeatedly a corresponding number of times for selectively depositing the respectively desired material.

Four partial intermediate layer stacks are provided in the embodiment shown in FIG. 2C. Without restricting the general validity, in various embodiments the first partial intermediate layer 222 can be formed from zinc oxide (for example having the layer thickness of approximately 5 nm) and the second partial intermediate layer 224 can be formed from aluminum oxide (for example having the layer thickness of approximately 2 nm). A total layer thickness of the intermediate layer stack 226 of approximately 28 nm thus results in this embodiment.

In various embodiments, all the partial intermediate layers 222, 224 and thus also zinc oxide and also aluminum oxide, for example, are deposited by means of an atomic layer deposition method.

In various embodiments, partial intermediate layers or the intermediate layer can for example consist of conductive metal oxides such as zinc oxide, aluminum-doped zinc oxide, tin oxide, indium-doped tin oxide or alloys thereof or include one or a plurality of these materials. The partial intermediate layers or intermediate layer can be made very thin (one atomic layer to 100 nm). Given sufficiently thin layers, in various embodiments it is possible to deposit one intermediate layer or a plurality of partial intermediate layers composed of conductive oxides without masking, since the parasitic current path in parallel with the OLED can be disregarded. Since the atomic layer deposition layers can be made very thin, the use of dielectric oxides for the intermediate layer or the partial intermediate layers is also provided in various embodiments, since they do not bring about an appreciable series electrical resistance for the energization of the OLED. Examples of dielectric oxides which are provided for the atomic layer deposition intermediate layer or atomic layer deposition partial intermediate layers in various embodiments are aluminum oxide, titanium oxide, hafnium oxide, lanthanum oxide and zirconium oxide or alloys thereof.

Any combinations of the abovementioned materials are possible, in principle, for the embodiment of the intermediate layer or of the partial intermediate layers. By means of choice of materials and layer thicknesses, the intermediate layer or the partial intermediate layers can be adapted in terms of the function thereof to the organic materials and the transparent metallic top electrode.

As is shown in a fourth partial structure 230 in FIG. 2D, a transparent electrically conductive (for example metallic) top contact 232, for example in the form of a second electrode 232, is deposited onto the free surface of the intermediate layer (or of the intermediate layer stack 226), which clearly forms or form a growth layer or a growth layer stack. The second electrode 232 can be formed by applying a (for example optically transparent) metal layer having a layer thickness of less than or equal to 30 nm.

The metal layer may include at least one of the following metals: aluminum, barium, indium, silver, copper, gold, magnesium, samarium, platinum, palladium, calcium and lithium and combinations thereof or this metal or a compound composed of this metal or composed of a plurality of these metals, for example an alloy.

The second electrode 232 including the metal layer is, for example if the first electrode 204 is an anode, a cathode. In this case, the electrode growth layer 226 is arranged on that side of the second electrode 232 which faces the substrate 202.

In various embodiments, the transparent metallic top electrode 232 has a 10 nm thick layer composed of silver or consists thereof, wherein the transparent metallic top electrode 232 can be applied by means of thermal evaporation.

In various embodiments, the transparent electrically conductive top contact 232 can also be applied by means of sputtering. In various embodiments, the transparent electrically conductive top contact 232 can have a layer thickness in a range of approximately 5 nm to approximately 30 nm, for example a layer thickness in a range of approximately 10 nm to approximately 20 nm.

As is shown in a fifth partial structure 240 in FIG. 2E, an optical adapting layer 242 for coupling out light is applied, for example deposited or sputtered, onto the free surface of the transparent electrically conductive top contact 232.

The OLED illustrated in FIG. 2E as an implementation of an electronic component in accordance with various embodiments is configured as a top/bottom emitter.

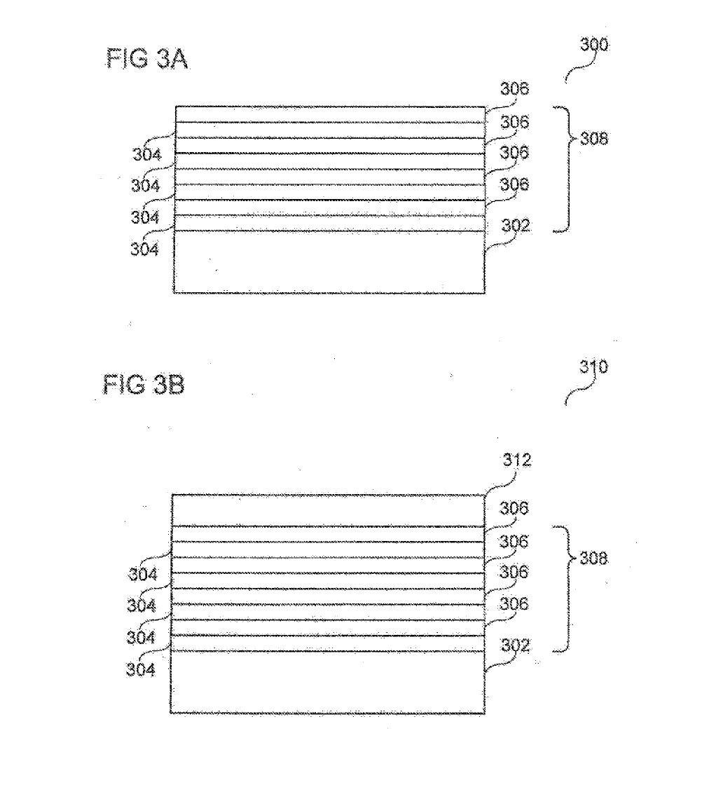

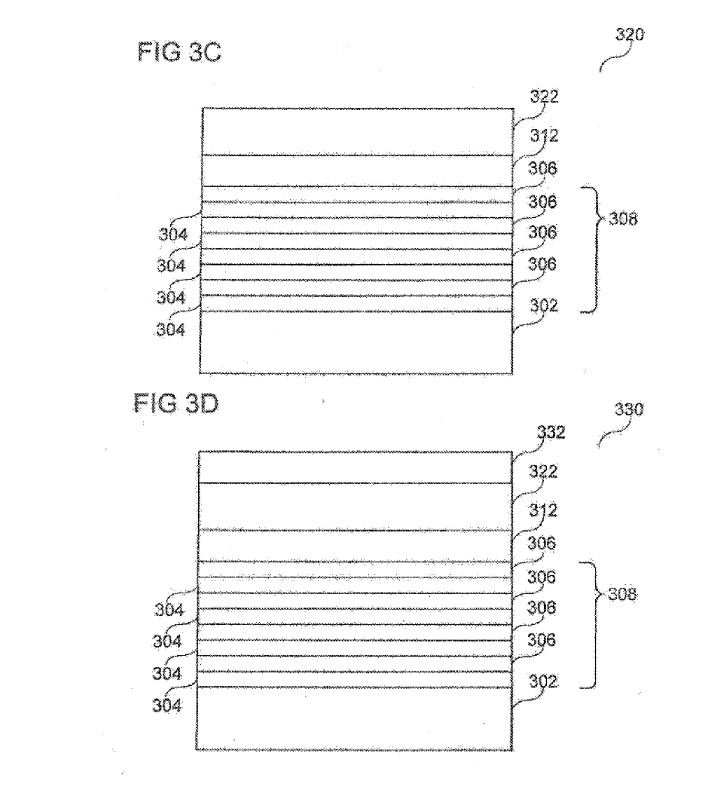

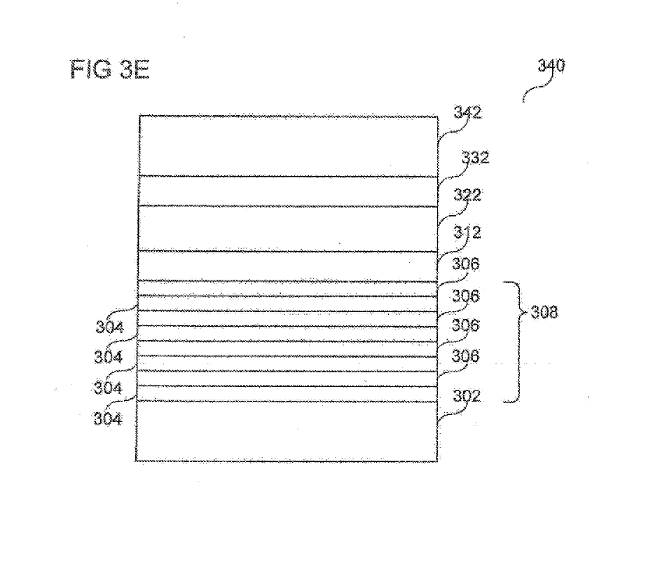

FIGS. 3A to 3E show schematically simplified side views of an electronic component, for example of an organic light emitting diode (OLED), in accordance with one embodiment in a partial section at different points in time during the production of the electronic component.

As is shown in a first partial structure 300 in FIG. 3A, one or a plurality of transparent intermediate layers (also designated as one or a plurality of electrode growth layer(s) hereinafter) is or are applied to a substrate 302.

The substrate 302 can be a transparent substrate 302. However, the substrate 302 can also be a nontransparent substrate 302. By way of example, the substrate may include glass, quartz, sapphire, plastic film(s), metal, metal film(s), silicon wafers or some other suitable substrate material.

In various embodiments, the at least one intermediate layer is applied by means of an atomic layer deposition method. The at least one intermediate layer or the intermediate layer stack 308 formed by a plurality of intermediate layers can have a layer thickness in the nanometers range, for example a layer thickness in a range of approximately 0.1 nm to approximately 200 nm, for example a layer thickness in a range of approximately 1 nm to approximately 8 nm, for example a layer thickness in a range of approximately 3 nm to approximately 3.5 nm, for example a layer thickness of greater than or equal to 1.5 nm. The layer thickness of the electrode growth layer(s) can be in each case or overall in various configurations for example less than or equal to 7 nm. FIG. 3A illustrates an intermediate layer stack 308 having a plurality of partial intermediate layers 304, 306 which are or have been applied in each case by means of an atomic layer deposition method. In various embodiments, a plurality of different materials, for example two different materials, can be provided, wherein each material forms a respective partial intermediate layer 304, 306. In various embodiments, the respective partial intermediate layers 304, 306 can be deposited from respectively alternately deposited different materials by means of an atomic layer deposition method. Thus, by way of example, a first partial intermediate layer 304 can be deposited from a first material (for example an oxide, nitride, carbide or some other material suitable for deposition by means of an atomic layer deposition method, for example zinc oxide), with a layer thickness of a few nanometers (for example onto the free surface of the substrate 302), for example with a layer thickness in a range of approximately 2 nm to approximately 8 nm, for example with a layer thickness in a range of approximately 3 nm to approximately 7 nm, for example with a layer thickness in a range of approximately 4 nm to approximately 6 nm, for example with a layer thickness of approximately 5 nm. Furthermore, by way of example, it is possible to deposit onto the first partial intermediate layer 304 a second partial intermediate layer 306 composed of a second material (for example an oxide, nitride, carbide or some other material suitable for deposition by means of an atomic layer deposition method, for example zinc oxide), which differs from the first material, for example, with a layer thickness of a few nanometers, for example with a layer thickness in a range of approximately 0.5 nm to approximately 8 nm, for example with a layer thickness in a range of approximately 1 nm to approximately 5 nm, for example with a layer thickness in a range of approximately 1.5 nm to approximately 3 nm, for example with a layer thickness of approximately 2 nm. It is then possible once again to deposit a further first partial intermediate layer 304 onto the second partial intermediate layer 306, a further second partial intermediate layer 306 onto the further first partial intermediate layer 304, etc. The formation of a plurality of partial intermediate layer stacks (wherein each partial intermediate layer stack may include a first partial intermediate layer 304 and a second partial intermediate layer 306), can be repeated as often as desired, in principle; by way of example, it is possible to provide two, three, four, five, six, seven or more partial intermediate layer stacks (depending on the desired total thickness of the intermediate layer stack). The atomic layer deposition method is carried out repeatedly a corresponding number of times for selectively depositing the respectively desired material.

Four partial intermediate layer stacks are provided in the embodiment shown in FIG. 3A. Without restricting the general validity, in various embodiments the first partial intermediate layer 304 can be formed from zinc oxide (for example having the layer thickness of approximately 5 nm) and the second partial intermediate layer 306 can be formed from aluminum oxide (for example having the layer thickness of approximately 2 nm). A total layer thickness of the intermediate layer stack 308 of approximately 28 nm thus results in this embodiment.

In various embodiments, all the partial intermediate layers 304, 306 and thus also zinc oxide and also aluminum oxide, for example, are deposited by means of an atomic layer deposition method.

In various embodiments, partial intermediate layers or the intermediate layer can for example consist of conductive metal oxides such as zinc oxide, aluminum-doped zinc oxide, tin oxide, indium-doped tin oxide or alloys thereof or include one or a plurality of these materials. The partial intermediate layers or intermediate layer can be made very thin (one atomic layer to 100 nm). Given sufficiently thin layers, in various embodiments it is possible to deposit one intermediate layer or a plurality of partial intermediate layers composed of conductive oxides without masking, since the parasitic current path in parallel with the OLED can be disregarded. Since the atomic layer deposition layers can be made very thin, the use of dielectric oxides for the intermediate layer or the partial intermediate layers is also provided in various embodiments, since they do not bring about an appreciable series electrical resistance for the energization of the OLED. Examples of dielectric oxides which are provided for the atomic layer deposition intermediate layer or atomic layer deposition partial intermediate layers in various embodiments are aluminum oxide, titanium oxide, hafnium oxide, lanthanum oxide and zirconium oxide or alloys thereof.

Any combinations of the abovementioned materials are possible, in principle, for the embodiment of the intermediate layer or of the partial intermediate layers. By means of choice of materials and layer thicknesses, the intermediate layer or the partial intermediate layers can be adapted in terms of the function thereof a transparent metallic first electrode to be formed, as will be explained in even greater detail below.

In various embodiments, any (electrically conductive or dielectric) material which can be deposited by means of an atomic layer deposition method can be provided for the intermediate layer or the partial intermediate layers.

As is shown in a second partial structure 310 in FIG. 3B, a first electrode 310, also designated as bottom electrode 310 hereinafter, is applied, for example deposited, onto the free surface of the intermediate layer or of the intermediate layer stack 308.

In various embodiments, the bottom electrode 310 can be an anode, for example, and can, for example, have been formed or be formed from indium-doped tin oxide (ITO) or include from one of the following metals: aluminum, barium, indium, silver, gold, magnesium, calcium and lithium and combinations thereof or this metal or a compound composed of this metal or composed of a plurality of these metals, for example an alloy.

In various embodiments, the substrate 302 and/or the first electrode 312 can be embodied as transparent.

In various embodiments, the first electrode 312 can be applied by means of sputtering or by means of thermal evaporation. In various embodiments, the first electrode 312 can have a layer thickness in a range of approximately 5 nm to approximately 30 nm, for example a layer thickness in a range of approximately 10 nm to approximately 20 nm.

As is shown in a third partial structure 320 in FIG. 3C, one or a plurality of organic functional layers 322 for charge transport and for generating light, such as, for example, a fluorescent and/or a phosphorescent emitter layer, is or are applied to the first electrode 312.

Examples of emitter materials which can be provided in the electronic component, for example an OLED, in accordance with various embodiments include organic or organometallic compounds, such as derivatives of polyfluorene, polythiophene and polyphenylene (e.g. 2- or 2,5-substituted poly-p-phenylene vinylene), and metal complexes, for example iridium complexes such as blue phosphorescent FIrPic (Bis(3,5-difluoro-2-(2-pyridyl)phenyl-(2-carboxypyridyl)iridium III), green phosphorescent Ir(ppy)₃ (Tris(2-phenylpyridine)iridium III), red phosphorescent Ru (dtb-bpy)₃*2(PF₆) (Tris[4,4′-di-tert-butyl-(2,2′)-bipyridine]ruthenium(III) complex) and blue fluorescent DPAVBi (4,4-Bis[4-(di-p-tolyamino)styryl]biphenyl), green fluorescent TTPA (9,10-Bis[N,N-di-(p-tolyl)amino]anthracene) and red fluorescent DCM2 (4-dicyanomethylene)-2-methyl-6-julolidyl-9-enyl-4H-pyrane) as non-polymeric emitters. Such non-polymeric emitters can be deposited by means of thermal evaporation, for example. Furthermore, it is possible to use polymer emitters, which can be deposited, in particular, by means of wet-chemical methods such as spin coating, for example.

The emitter materials can be embedded in a matrix material in a suitable manner.

The emitter materials of the emitter layers of the electronic component can be selected, for example, such that the electronic component emits white light. The emitter layer may include a plurality of emitter materials that emit in different colors (for example blue and yellow, or blue, green and red); alternatively, the emitter layer can also be constructed from a plurality of partial layers, such as a blue fluorescent emitter layer, a green phosphorescent emitter layer and a red phosphorescent emitter layer. By mixing the different colors, the emission of light having a white color impression can result. Alternatively, provision can also be made for arranging a converter material in the beam path of the primary emission generated by said layers, which converter material at least partly absorbs the primary radiation and emits a secondary radiation having a different wavelength, such that a white color impression results from a (not yet white) primary radiation by virtue of the combination of primary and secondary radiation.

It is possible to provide further organic functional layers which serve, for example, to further improve the functionality and thus the efficiency of the electronic component.

It is pointed out that, in alternative embodiments, any suitable form of light emitting functional layers, for example organic functional layers, can be provided and the invention is not restricted to a specific type of functional layer(s).

As is shown in a fourth partial structure 330 in FIG. 3D, a transparent electrically conductive (for example metallic) top contact 332, for example in the form of a second electrode 332, is deposited onto the free surface of the third partial structure more precisely onto the one or the plurality of organic functional layers 322. The second electrode 332 can be formed by applying a (for example optically transparent) metal layer having a layer thickness of less than or equal to 30 nm.

The metal layer may include at least one of the following metals: aluminum, barium, indium, silver, gold, magnesium, calcium and lithium and combinations thereof or this metal or a compound composed of this metal or composed of a plurality of these metals, for example an alloy.

The second electrode 332 including the metal layer is, for example if the first electrode 312 is an anode, a cathode.

In various embodiments, the transparent metallic top electrode 332 has a 10 nm thick layer composed of silver or consists thereof, wherein the transparent metallic top electrode 332 can be applied by means of thermal evaporation.

In various embodiments, the transparent electrically conductive top contact 332 can also be applied by means of sputtering. In various embodiments, the transparent electrically conductive top contact 332 can have a layer thickness in a range of approximately 5 nm to approximately 30 nm, for example a layer thickness in a range of approximately 10 nm to approximately 20 nm.

As is shown in a fifth partial structure 340 in FIG. 3E, an optical adapting layer 342 for coupling out light is applied, for example deposited or sputtered, onto the free surface of the transparent electrically conductive top contact 332.

The OLED illustrated in FIG. 3E as an implementation of an electronic component in accordance with various embodiments is configured as a bottom emitter.

In various embodiments, provision can be made for providing an electrode growth layer or an electrode growth layer stack both below the first electrode and below the second electrode of the electronic component.

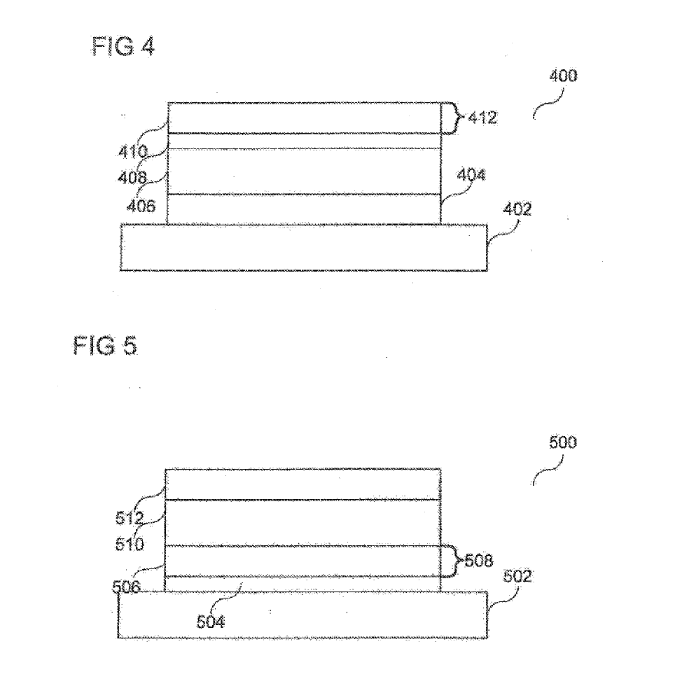

FIG. 4 shows a schematically simplified side view of an electronic component 400 in accordance with one embodiment, which is configured as a top/bottom emitter.

A first electrode 404 is arranged on a substrate 402, e.g. a glass substrate. The first electrode 404 can be an anode, for example, and can be formed from indium-doped tin oxide (ITO), for example.

An organic functional layer 406, such as, for example, a fluorescent and/or phosphorescent emitter layer, is arranged on the first electrode 404.

A growth layer 408 is arranged on the organic functional layer 406. The growth layer 408 can be e.g. 3 nm thick and can be deposited by means of facing target sputtering.

A growth electrode, e.g. in the form of a 10 nm thick metal layer 410, is deposited as second electrode on the growth layer 408. The metal layer 410 can be deposited by means of sputtering, for example.

The second electrode 412 including the metal layer 410 is, if the first electrode 404 is an anode, a cathode. In this case, the growth layer 408 is arranged for example on that side of the second electrode 412 which faces the substrate 402.

FIG. 5 shows a schematically simplified side view of an electronic component 500 in accordance with another embodiment, which is configured as a bottom emitter.

A growth layer 504 is arranged on the substrate 502, such as a glass substrate, and a growth electrode in the form of a metal layer 508 as first electrode 510 is arranged on the growth layer 504. The first electrode 510 can be configured as an anode.

In accordance with various embodiments, the growth layer 504 is arranged on that side of the first electrode 510 which faces the substrate 502.

The growth layer 504 can serve to improve the surface on which a growth layer has been applied, i.e. to treat it in such a way that the metal layer 508 can be deposited thinly, smoothly and homogeneously in order to enable improved energization and an improved transparency of the electronic component 500.

An organic functional layer 512 is arranged on the metal layer 508. The organic functional layer 512 may include an emitter layer.

In various embodiments, the second electrode 514 is arranged on the organic functional layer 512. The second electrode 514 is, if the first electrode 510 is an anode, a cathode. It can be, for example, a conventional 20 nm thick silver layer.

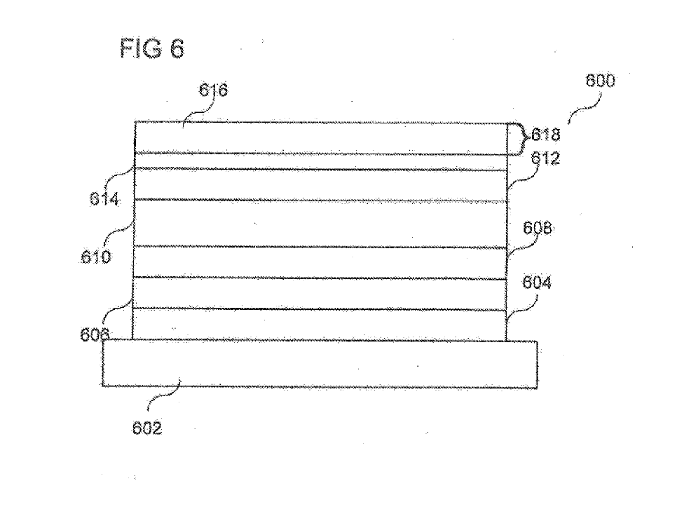

FIG. 6 shows a schematically simplified side view of an electronic component 600 in accordance with another embodiment, which is configured as a top emitter.

A first electrode 604 is arranged on a substrate 602. The first electrode 604 can be, as shown in FIG. 6, an anode and can be formed from indium-doped tin oxide (ITO) for example.

A hole injection layer 606 is arranged on the first electrode 604 and a hole transport layer 608 is arranged on said hole injection layer. The hole injection layer 606 and the hole transport layer 608 can be deposited by means of thermal evaporation.

A further organic functional layer 610, such as, for example, a fluorescent and/or phosphorescent emitter layer, is arranged on the hole transport layer 608.

An electron transport layer 612, which can likewise be deposited by means of thermal evaporation, is arranged on the organic functional layer 610. A growth layer 614 is arranged on the electron transport layer 612. The growth layer 614 can be e.g. 3 nm thick and deposited by means of facing target sputtering.

A growth electrode, e.g. in the form of a 10 nm thick metal layer 616, is deposited as second electrode on the growth layer 614. The metal layer 616 can preferably be deposited by means of sputtering.

The second electrode 618 including the metal layer 616 is, as shown in FIG. 6, a cathode.

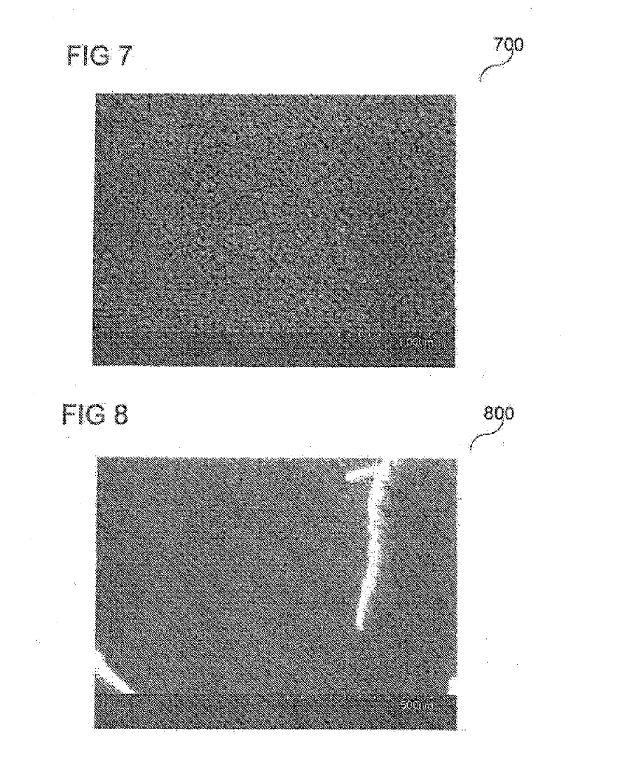

FIG. 7 shows an SEM micrograph 700 of a thin silver layer deposited on a glass substrate. The silver layer is 12 nm thick and was applied to the glass substrate by means of thermal evaporation. As can be seen in FIG. 7, the silver layer tends greatly toward island formation; the glass substrate can be discerned between the metal islands. Therefore, the silver layer is not formed smoothly and homogeneously on the glass substrate. The sheet resistance of this silver layer, measured using a four-tip measuring instrument, is 19.3Ω/□±1.9Ω/□.

FIG. 8 shows an SEM micrograph 800 of a 12 nm silver layer deposited on an organic system support by means of thermal evaporation. The organic system support is deposited on a glass substrate and consists of a conventional matrix material, such as, for example, α-NPD (N,N′-diphenyl-N,N′-bis(1-naphthyl)-1,1′ biphenyl-4,4″diamine. The tendency of the silver layer toward island formation is significantly less than in FIG. 7; however, distinct cracks can be discerned. The sheet resistance of this silver layer, measured using a four-tip measuring instrument, is 7.13Ω/□±0.37Ω/□.

FIG. 9 shows an SEM micrograph 900 of a 12 nm thick silver layer deposited on a 17 nm thick ITO growth layer by means of sputtering in accordance with various embodiments. The ITO growth layer in turn was applied on a 90 nm thick organic system support, such as was indicated above with reference to FIG. 8, for example.

The organic system support was applied to a glass substrate. As can be seen in FIG. 9, the silver layer is formed in a smooth and closed manner. The sheet resistance of this silver layer, measured using a four-tip measuring instrument, is 4.48Ω/□±0.20Ω/□.

The thin amorphous growth layer in accordance with various embodiments makes it possible that the metal layer—in comparison with conventional metal layers or electrode layers having a thickness of e.g. 20 nm—can be deposited thinly, smoothly and as a closed layer on the growth layer.

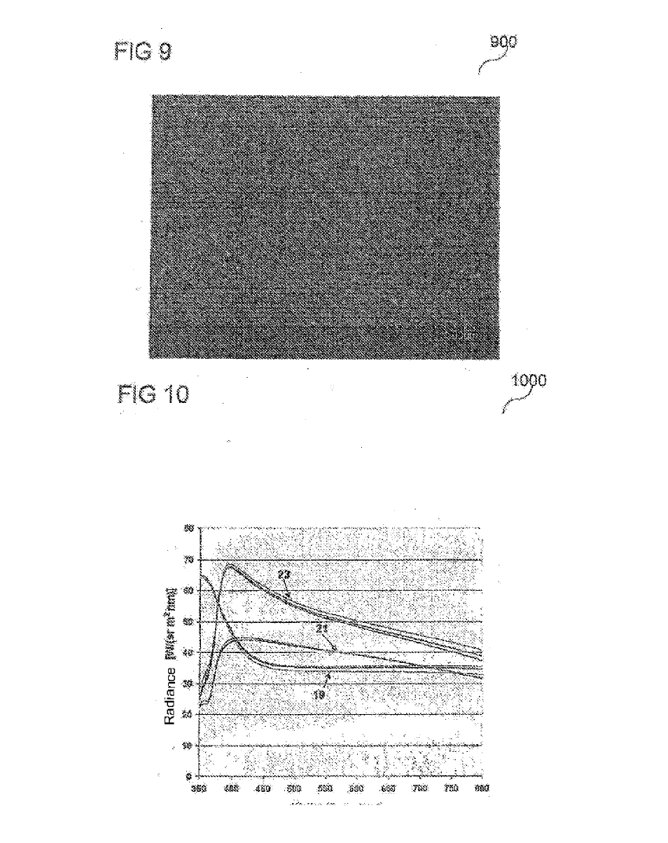

FIG. 10 shows a graph 1000 showing the result of a measurement of the transparency of the silver layers (silver layer on glass substrate in accordance with FIG. 7, silver layer on organic system support on glass substrate in accordance with FIG. 8, and silver layer on ITO layer on organic system support on glass substrate in accordance with FIG. 8) from FIG. 7 to FIG. 9. Three measurements were carried out per example. The transparency [%] relative to the wavelength [nm] is indicated.

The silver layer on glass system support 19 from FIG. 7 exhibits a radiance of approximately 65% at a wavelength of approximately 335 nm, which falls to a minimum value of approximately 35% starting from approximately 410 nm and remains constant at higher wavelengths.

The silver layer on organic system support 21 from FIG. 8 exhibits a transparency maximum of approximately 43% at approximately 400 nm. The transparency falls slowly to a value of approximately 32% at higher wavelengths.

The silver layer on indium-doped tin oxide (ITO) 23 in accordance with one embodiment from FIG. 9 exhibits a transparency maximum of approximately 68% at approximately 400 nm. The transparency is greater than 60% in the range of approximately 380 nm to approximately 450 nm. The transparency of the silver layer on indium-doped tin oxide 23 is significantly greater than that of the other layers 19 and 21.

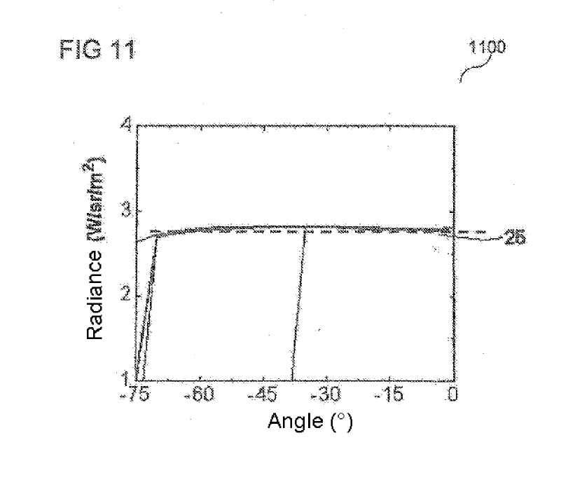

FIG. 11 shows the emission characteristics 1100 of an optoelectronic component in accordance with various embodiments. Three measurements were carried out. The emission characteristics are illustrated as radiance (specified in [W/(sr/m²)]) relative to the viewing angle (specified in degrees [°]). The unit “sr” denotes the steradian, i.e. the solid angle.

The emission characteristic 25 of the arrangement of an electronic component according to the invention as described in FIG. 6, which is embodied as a top emitting OLED, for example, exhibits a substantially Lambertian emission characteristic (the Lambertian emission characteristic is depicted as a dashed line and does not bear a reference sign).

A method for producing an electronic component is provided in various embodiments. The method may include applying an electrode growth layer on or above a substrate by means of an atomic layer deposition method; and applying an electrode on the electrode growth layer.

In one configuration of these embodiments, the electrode growth layer can be applied with a layer thickness in a range of 0.1 nm to 200 nm.

In another configuration of these embodiments, applying an electrode growth layer may include applying a plurality of partial layers forming the electrode growth layer.

In another configuration of these embodiments, the electrode can be formed by applying a metal layer having a layer thickness of less than or equal to 30 nm.

In another configuration of these embodiments, the metal layer may include at least one metal selected from the group consisting of aluminum, barium, indium, silver, copper, gold, platinum, palladium, samarium, magnesium, calcium and lithium and combinations thereof or consists of said metal or a compound composed of said metal or composed of a plurality of said metals, for example an alloy.

In another configuration of these embodiments, the electronic component can be formed as an organic electronic component, and furthermore an additional electrode and at least one organic functional layer arranged between the electrode and the additional electrode can be formed.

In another configuration of these embodiments, a layer structure can be formed on the electrode. Forming the layer structure may include forming the additional electrode on the organic functional layer.

In another configuration of these embodiments, the electronic component can be formed as an organic light emitting diode.

In another configuration of these embodiments, the electrode can be embodied as a transparent electrode.

In another configuration of these embodiments, the additional electrode can be embodied as a transparent electrode.

Various embodiments furthermore provide an electronic component which may include a substrate; an electrode growth layer on the substrate; and an electrode on the electrode growth layer. The electrode growth layer can be embodied as an atomic layer deposition layer.

In one configuration of these embodiments, the electrode can be embodied as a transparent electrode.

In another configuration of these embodiments, the electrode growth layer can have a layer thickness in a range of 0.1 nm to 200 nm.

In another configuration of these embodiments, the electrode growth layer can have a plurality of partial layers forming the electrode growth layer.

In another configuration of these embodiments, the electronic component can be embodied as an organic electronic component; and the electronic component may furthermore include an additional electrode and at least one organic functional layer arranged between the electrode and the additional electrode.

In another configuration of these embodiments, the additional electrode can be embodied as a transparent electrode.

In another configuration of these embodiments, the layer structure can have an additional electrode on the organic layer structure and an organic functional layer on the electrode. The electrodes can be formed on the electrode growth layer, and the electrode growth layer can be formed on the substrate.

In another configuration of these embodiments, the electronic component can be embodied as an organic light emitting diode.

The embodiments can be varied further in any desired manner. It should furthermore be taken into consideration that the invention is not restricted to these examples, but rather permits further configurations and embodiments not presented here.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. A method for producing an electronic component, wherein the method comprises:
applying an electrode growth layer on or above a layer structure by means of an atomic layer deposition method; and
applying an electrode on the electrode growth layer;
wherein the electrode growth layer is applied with a layer thickness in a range of approximately 1.5 nm to approximately 28 nm.

2. The method as claimed in claim 1,
wherein the electrode growth layer is applied with a layer thickness in a range of 15 nm to 10 nm.

3. The method as claimed in claim 1,
wherein applying an electrode growth layer comprises applying a plurality of partial layers forming the electrode growth layer.

4. The method as claimed in claim 1,
wherein the electrode is formed by applying a metal layer having a layer thickness of less than or equal to 30 nm.

5. The method as claimed in claim 4,
wherein the metal layer comprises at least one metal selected from the group consisting of aluminum, barium, indium, silver, copper, gold, platinum, palladium, samarium, magnesium, calcium and lithium and combinations thereof or consists of said metal or a compound composed of said metal or composed of a plurality of said metals, in particular an alloy.

6. The method as claimed in claim 1,
wherein the electronic component is formed as an organic electronic component; and
wherein furthermore an additional electrode and at least one organic functional layer arranged between the electrode and the additional electrode are formed.

7. The method as claimed in claim 6,
wherein the layer structure has a substrate; and
wherein forming the layer structure comprises:
forming the additional electrode on a substrate;
forming the organically functional layer on the additional electrode;
wherein the electrode growth layer is formed on the organic functional layer.

8. The method as claimed in claim 1,
wherein the electronic component is formed as an organic light emitting diode.

9. The method as claimed in claim 1,
wherein the electrode is embodied as a transparent electrode.

10. The method as claimed in claim 7,
wherein the additional electrode is embodied as a transparent electrode.

11. An electronic component, comprising:
a layer structure;
an electrode growth layer on the layer structure; and
an electrode on the electrode growth layer;
wherein the electrode growth layer is embodied as an atomic layer deposition layer;
wherein the electrode growth layer has a layer thickness in a range of approximately 1.5 nm to approximately 28 nm.

12. The electronic component as claimed in claim 11,
wherein the electrode is embodied as a transparent electrode.

13. The electronic component as claimed in claim 11,
wherein the electrode growth layer has a layer thickness in a range of approximately 1.5 nm to approximately 10 nm.

14. The electronic component as claimed in claim 11,
wherein the electrode growth layer has a plurality of partial layers forming the electrode growth layer.

15. The electronic component as claimed in claim 11,
wherein the electronic component is embodied as an organic electronic component; and
wherein the electronic component furthermore has an additional electrode and at least one organic functional layer arranged between the electrode and the additional electrode.

16. The electronic component as claimed in claim 15,
wherein the additional electrode is embodied as a transparent electrode.

17. The electronic component as claimed in claim 15,
wherein the layer structure has:
an additional electrode on a substrate;
an organic functional layer on the additional electrode;
wherein the electrode growth layer is formed on the organic functional layer.

18. The electronic component as claimed in claim 11,
wherein the electronic component is embodied as an organic light emitting diode.

19. A method for producing an electronic component, wherein the method comprises:
applying an electrode growth layer on or above a substrate by means of an atomic layer deposition method; and
applying an electrode on the electrode growth layer;
wherein the electrode growth layer is applied with a layer thickness in a range of approximately 1.5 nm to approximately 28 nm.

20. (canceled)

21. An electronic component, comprising:
a substrate;
an electrode growth layer on the substrate; and
an electrode on the electrode growth layer;
wherein the electrode growth layer is embodied as an atomic layer deposition layer;
wherein the electrode growth layer has a layer thickness in a range of approximately 1.5 nm to approximately 28 nm.

22. (canceled)
